(19) United States
(12) Patent Application Publication
(10) Pub. No.: US 2023/0273090 A1
(43) Pub. Date: Aug. 31, 2023

(54) HORIZONTAL TWO-DIMENSIONAL DISPLACEMENT RECONSTRUCTION METHOD FOR LATTICE TOWER STRUCTURE BASED ON MULTI-SOURCE HETEROGENEOUS DATA FUSION

(71) Applicant: DALIAN UNIVERSITY OF TECHNOLOGY, Dalian, Liaoning (CN)

(72) Inventors: Xing FU, Dalian, Liaoning (CN); Qing ZHANG, Dalian, Liaoning (CN); Liang REN, Dalian, Liaoning (CN)

(21) Appl. No.: 17/772,654

(22) PCT Filed: Sep. 3, 2021
(86) PCT No.: PCT/CN2021/116423

§ 371 Date: Apr. 28, 2022

(51) Int. Cl. G01M 7/02

(52) U.S. Cl. CPC G01M 7/02

(57) ABSTRACT

The present invention belongs to the field of monitoring technology and signal analysis of lattice tower structures, and discloses a horizontal two-dimensional displacement reconstruction method for a lattice tower structure based on multi-source heterogeneous data fusion. a lattice tower is simplified into a thin-walled three-dimensional variable section cantilever beam, a two-dimensional strain-displacement mapping method is used to calculate the horizontal two-dimensional displacement with low sampling rate, and finally a multi-rate Kalman filter algorithm is used to fuse the displacement with horizontal two-dimensional acceleration to obtain the horizontal two-dimensional displacement with high sampling rate. A data fusion method of the present invention needs less sensors, is simple in calculation process and accurate in calculation results, and has strong operability and practicability.

### TECHNICAL FIELD

The present invention belongs to the field of health monitoring technology and signal analysis of lattice tower structures, and particularly relates to a multi-source heterogeneous data fusion method for horizontal two-dimensional displacement reconstruction of a lattice tower structure.

### BACKGROUND

The purpose of structural health monitoring is to assess the health of the structure and give a reference on whether the structure needs to be maintained, which plays a vital role in the safe operation of a large infrastructure during a service period. In recent years, the lattice tower has played an important role in the construction of signal base stations, transmission line engineering and meteorological monitoring, and is extremely necessary to carry out related research on structural health monitoring of the lattice tower. Dynamic displacement is one of the key parameters for evaluating the safety performance of the structure, and has received wide attention because it provides information directly related to structural deformation. However, it is difficult for the lattice tower to directly measure dynamic displacement due to complex structural characteristics and cost. Indirect reconstruction of dynamic displacement using existing common data such as acceleration and strain needs to be further studied.

In the past few decades, scholars have done a lot of work on the research of dynamic displacement reconstruction. For example, the method of estimating the initial velocity is used to correct the double integral error of acceleration, and segmentation calculation of the static response of the structure, but there is no unified guideline for how to segment. Details can be found in PARK K T, KIM S H, PARK H S, et al. The determination of bridge displacement using measured acceleration [J]. Engineering Structures, 2005, 27(3): 371-378. In addition, strain data is also used to reconstruct dynamic displacement. Bridge vibration displacement is estimated using theoretical displacement mode shapes of simply supported beams and fiber grating sensors, or the shape of a rotating structure is estimated using strain and displacement-strain relationships acquired by a distributed fiber grating sensor. Details can be found in SHIN S, LEE S U, KIM Y, et al. Estimation of bridge displacement responses using FBG sensors and theoretical mode shapes [J]. Structural Engineering and Mechanics, 2012, 42(2): 229-245.And KIM H I, KANG L H, HAN J H. Shape estimation with distributed fiber Bragg grating sensors for rotating structures [J]. Smart Materials and Structures, 2011, 20(3): 035011. By using the Kalman filter algorithm to fuse the velocity of a laser Doppler vibrometer and the displacement collected by lidar, the dynamic displacement is estimated in real time, thereby overcoming the shortcomings of poor lidar accuracy and low sampling rate and obtaining dynamic displacement with high sampling rate and high accuracy. Details can be found in KIM K, SOHN H. Dynamic displacement estimation by fusing LDV and LiDAR measurements via smoothing based Kalman filtering [J]. Mechanical Systems and Signal Processing, 2017, 82: 339-355. However, the existing data fusion methods are only suitable for one-direction displacement reconstruction of uniform beam structures, and not suitable for the variable section structure of the lattice tower, and the actual structure mainly generates the dynamic displacement synthesized by the horizontal two-dimensional displacement. There is no corresponding data fusion method for horizontal two-dimensional displacement reconstruction of the complex structure of the lattice tower structure.

Aiming at the deficiency that the existing data fusion method is only suitable for the one-direction displacement reconstruction of uniform beams, the present invention proposes a data fusion method suitable for the horizontal two-dimensional displacement reconstruction of the lattice tower structure, with the core of uniform arrangement of strain sensors along a height range of a tower body, arrangement of an acceleration sensor at a displacement point to be measured and decomposition of the strain along in-plane and out-of-plane vibration directions to calculate the strain-derived displacement using a strain-displacement mapping method. The mature multi-rate Kalman filter algorithm is used to process the acceleration and strain-derived displacement to calculate the horizontal two-dimensional dynamic displacement with higher sampling rate and accuracy, which provides a new method for indirectly measuring the horizontal two-dimensional dynamic displacement of the lattice tower structure.

### SUMMARY

The present invention provides a new data fusion method for horizontal two-dimensional displacement reconstruction of a lattice tower structure, and provides a new idea for the indirect measurement of the horizontal two-dimensional dynamic displacement of the lattice tower structure.

The technical solution of the present invention: a lattice tower is simplified into a thin-walled three-dimensional variable section cantilever beam, a two-dimensional strain-displacement mapping method is used to calculate the horizontal two-dimensional displacement with low sampling rate, and finally a multi-rate Kalman filter algorithm is used to fuse the displacement with horizontal two-dimensional acceleration to obtain the horizontal two-dimensional displacement with high sampling rate, comprising the following steps:

(1) evenly arranging 2M strain sensors along height on a left and a right main members of the lattice tower, with the minimum number of the strain sensors of 8; and arranging one horizontal two-dimensional acceleration sensor at a displacement point to be measured;

(2) decomposing data {ε_{left}}_{M×1} and {ε_{right}}_{M×1} collected by the strain sensors into {ε_{y}}_{M×1} and {ε_{z}}_{M×1} according to two main directions of vibration, wherein y and z are directions of the lattice tower along in-plane and out-of-plane vibration respectively;

$$\begin{matrix}{\{ {ε}_{y} \}}_{M \times 1} = \frac{{\{ {ε}_{left} \}}_{M \times 1} + {\{ {ε}_{right} \}}_{M \times 1}}{2} & ( 1 ) \\ {\{ {ε}_{z} \}}_{M \times 1} = \frac{{\{ {ε}_{left} \}}_{M \times 1} - {\{ {ε}_{right} \}}_{M \times 1}}{2} & ( 2 )\end{matrix}$$

(3) processing the decomposed strain data by using a stochastic subspace identification (SSI) method respectively, drawing a stability diagram according to processing results; then judging a vibration mode order n participating in vibration according to the obtained stability diagram, wherein n is a natural number and does not exceed M; and extracting first n-order strain mode shape matrixes and {Ψ_{y}}_{M×n}^{T} and {Ψ_{z}}_{M×n}^{T} in two directions;

(4) calculating functional relationships y(x) and z(x) between horizontal distances y and z from any point of the main material to two neutral layers, and a height x of the point from the ground according to the lattice tower;

(5) performing polynomial fitting on the first n-order strain mode shapes of the two directions and the height x of the strain sensor arrangement points from the ground, to obtain strain mode shape functions Ψᵢ^{y}(x) and Ψᵢ^{z}(x); then regarding the whole of

$$\frac{{Ψ}_{i}^{y} ( x )}{y ( x )} and \frac{{Ψ}_{i}^{z} ( x )}{z ( x )}$$

as a function, and expanding respectively according to Taylor formula; doubly integrating expansion results and substituting boundary conditions of bottom fixing of the lattice tower structure to obtain displacement mode shape functions Φᵢ^{y}(x) and Φᵢ^{z}(x);

$$\frac{{Ψ}_{i}^{y} ( x )}{y ( x )} = f ( x ) = \frac{f ( {x}_{0} )}{0 !} + \frac{{f}^{′} ( {x}_{0} )}{1 !} ( x - {x}_{0} ) + \frac{{f}^{″} ( {x}_{0} )}{2 !} {( x - {x}_{0} )}^{2} + ⋯ + \frac{{f}^{n} ( {x}_{0} )}{n !} {( x - {x}_{0} )}^{n} + {R}_{n} ( x ) \qquad ( 3 )$$

$${Φ}_{i}^{y} ( x ) = ( - \int \int f ( x ) {dx}^{2} ) \qquad ( 4 )$$

$$\frac{{Ψ}_{i}^{z} ( x )}{z ( x )} = g ( x ) = \frac{g ( {x}_{0} )}{0 !} + \frac{{g}^{′} ( {x}_{0} )}{1 !} ( x - {x}_{0} ) + \frac{{g}^{″} ( {x}_{0} )}{2 !} {( x - {x}_{0} )}^{2} + ⋯ + \frac{{g}^{n} ( {x}_{0} )}{n !} {( x - {x}_{0} )}^{n} + {Q}_{n} ( x ) \qquad ( 5 )$$

$${Φ}_{i}^{z} ( x ) = ( - \int \int g ( x ) {dx}^{2} ) \qquad ( 6 )$$

(6) solving modal coordinates {q_{y}}_{n×1} and {q_{z}}_{n×1} of the lattice tower during vibration by a least squares method under the condition that the strain mode shape matrixes {Ψ_{y}}_{M×n}^{T} and {Ψ_{z}}_{M×n}^{T} of the lattice tower and the strain data {ε_{y}}_{M×1} and {ε_{z}}_{M×1} after orthogonal decomposition are known;

{q_{y}}_{n×1}=({Ψ_{y}}_{M×n}^{T}·{Ψ_{y}}_{M×n})⁻¹·{Ψ_{y}}_{M×n}^{T}·{ε_{y}}_{M×1} (7)

{q_{z}}_{n×1}=({Ψ_{z}}_{M×n}^{T}·{Ψ_{z}}_{M×n})⁻¹·{Ψ_{z}}_{M×n}^{T}·{ε_{z}}_{M×1} (8)

(7) substituting the height coordinate x of the displacement point to be measured on the lattice tower into the two displacement mode shape functions Φᵢ^{y}(x) and Φᵢ^{z}(x) to obtain corresponding displacement mode shape function values, and multiplying the obtained displacement mode shape function values and the modal coordinates to obtain low sampling rate dynamic displacements u_{y} and u_{z} of the point;

(8) taking the y-direction acceleration a_{y} of the displacement point to be measured collected by the acceleration sensor and the calculated y-direction displacement u_{y} as a set of state variables, and taking the z-direction acceleration a_{z} and the calculated z-direction displacement u_{z} as another set of state variables; and respectively inputting the state variables into multi-rate Kalman filter algorithm to reconstruct final horizontal two-dimensional dynamic displacement with high sampling rate. The Kalman filter algorithm can be found in KIM J, KIM K, SOHN H. Autonomous dynamic displacement estimation from data fusion of acceleration and intermittent displacement measurements [J]. Mechanical Systems and Signal Processing, 2014, 42(1-2): 194-205.

### Beneficial Effects of the Present Invention

(1) The proposed two-dimensional strain-displacement mapping method can directly calculate the horizontal two-dimensional dynamic displacement of the corresponding sampling rate from the strain, which solves the problem that it is difficult to calculate the displacement directly from the strain;

(2) The proposed data fusion method takes the acceleration and the strain-derived displacement as input values, and only needs to install strain and acceleration sensors on the lattice tower to achieve horizontal two-dimensional displacement reconstruction with high sampling rate;

(3) The method can comprehensively utilize the information of various sensors to realize the fusion of multi-source heterogeneous data, and can measure the horizontal two-dimensional dynamic displacement of the lattice tower in real time.

### DESCRIPTION OF DRAWINGS

FIG. 1 is a flow chart of implementation of the present invention; and

FIG. 2 is a sensor layout diagram of a lattice tower; (a) is a front view of a lattice tower, wherein circles represent strain sensors, boxes are horizontal two-dimensional acceleration sensors, and X axis also represents an imaginary neutral layer; (b) is a side view of a lattice tower, wherein X axis also represents an imaginary neutral layer.

### DETAILED DESCRIPTION

In order to make the invention purposes, features, and advantages of the present invention more obvious and understandable, the technical solutions in the embodiments of the present invention will be described clearly and completely below with reference to the drawings in the embodiments of the present invention. Obviously, the embodiments described below are only some, but not all of embodiments of the present invention. Based on the embodiments of the present invention, all other embodiments obtained by those of ordinary skill in the art without creative efforts shall fall within the protection scope of the present invention. Based on the embodiments in the present invention, all other embodiments obtained by those ordinary skilled in the art without contributing creative labor will belong to the protection scope of the present invention.

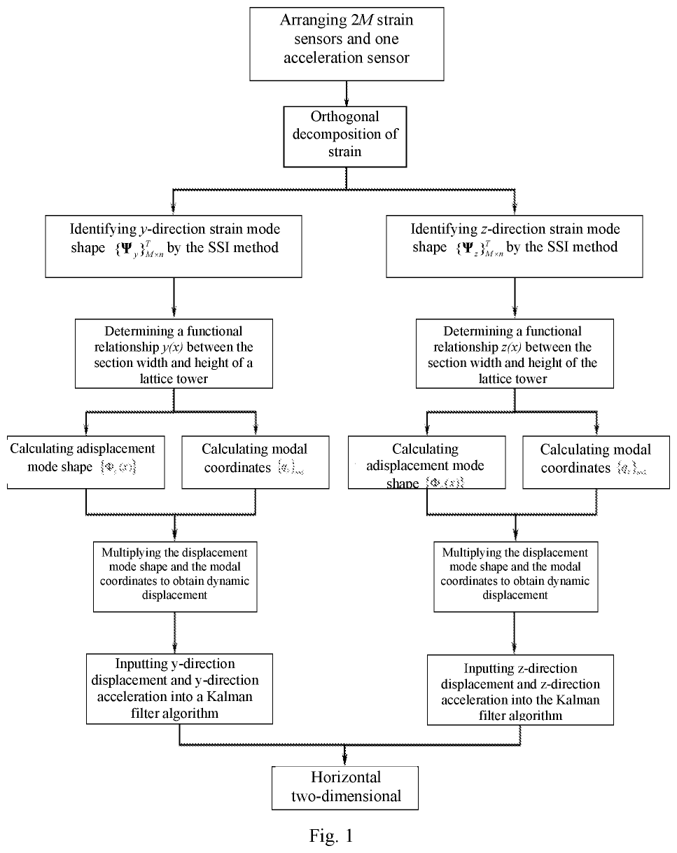

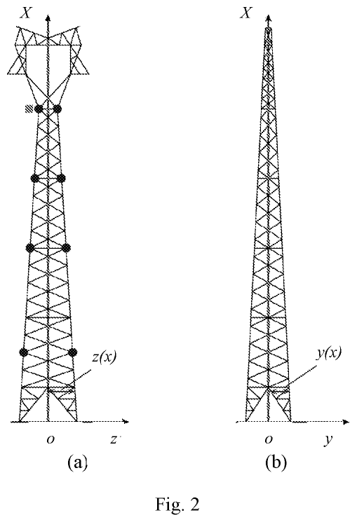

Referring to FIGS. 1-2, an embodiment of the present invention proposes a data fusion method for horizontal two-dimensional displacement reconstruction of a lattice tower structure.

Data source for implementation case: details can be found in ZHANG Q, FU X, REN L, et al. Modal parameters of a transmission tower considering the coupling effects between the tower and lines [J]. Engineering Structures, 2020, 220: 110947.

In the embodiments of the present invention, the establishment and the transient analysis of a numerical model of a lattice tower can use self-written programs or related commercial software. In the present embodiment, widely used finite element analysis software ANSYS is used as an example to realize the application of the data fusion method in the lattice tower structure, which is specifically described as follows in conjunction with a process shown in FIG. 1 and the technical solution of the present invention:

(1) In the embodiment, a lattice tower is a self-supporting iron tower with a total height of 34 m and is made of Q235 equilateral angle steel. The detailed information of the iron tower structure can be found in “FIG. 6” of “ZHANG Q, FU X, REN L, et al. Modal parameters of a transmission tower considering the coupling effects between the tower and lines [J]. Engineering Structures, 2020, 220: 110947.” A finite element model of the iron tower is established by ANSYS software, and BEAM188 element is used to simulate rods of the lattice tower. Rigid joints are used to simplify the connection between the rods, and an ideal elastic-plastic model is used for steel constitutive.

Because the two-dimensional strain-displacement mapping method in the data fusion method needs to consider the first three-order mode shapes, in the present embodiment, a total of 8 strain measuring points are arranged on left and right main materials, and at the same time, one two-dimensional acceleration measuring point is arranged at the junction of a tower head and a tower body, which is also the displacement point to be measured. The numerical model of the lattice tower is established according to design drawings.

(2) The y-direction load and z-direction load applied in the present embodiment can be found in “FIG. 6” of “ZHANG Q, FU X, REN L, et al. Modal parameters of a transmission tower considering the coupling effects between the tower and lines [J]. Engineering Structures, 2020, 220: 110947.”The solution type of ANSYS software analysis is “an type, trans”. After the solution of the applied load is completed, the strain response and acceleration response of the strain measuring points can be extracted. The strain sampling rate is set to 10 Hz, and the acceleration sampling rate is set to 100 Hz.The data collected by the strain sensors is decomposed according to the main directions of two main vibrations, and then the SSI method is used to process the strain response after the orthogonal decomposition. Assuming that the order is set to 100, the identified strain mode shapes and corresponding height coordinates are extracted.

(3) Functional relationships between horizontal distances y and z from any point of the main member to two neutral layers, and a height x of the point from the ground are calculated according to the size of the lattice tower, and are linear functional relationships in the present embodiment.

(4) Polynomial fitting is performed on the strain mode shapes of the two directions and the height coordinates of the lattice tower to obtain strain mode shape functions; regarding

$$\frac{{Ψ}_{i}^{y} ( x )}{y ( x )} and \frac{{Ψ}_{i}^{z} ( x )}{z ( x )}$$

as functions as a whole, and expanding respectively according to Taylor formula; and taking double indefinite integrals of expansion results, and substituting boundary conditions to obtain displacement mode shape functions Φᵢ^{y}(x) and Φᵢ^{z}(x).

(5) Mode shape coordinates are solved from the strain response after orthogonal decomposition and the strain mode shapes in two directions respectively by a least squares method.

(6) The height coordinates of the displacement point to be measured are substituted into the displacement mode shape functions to obtain function values, and the displacement mode shape function values and the mode shape coordinates are multiplied to obtain the horizontal two-dimensional dynamic displacement with low sampling rate.

(7) The existing multi-rate Kalman filter algorithm is used to process the low sampling rate dynamic displacement and acceleration in two directions respectively to obtain the horizontal two-dimensional dynamic displacement with high sampling rate.

When the present invention is used, it should be noted that: firstly, the number of the strain measuring points on each main member of the lattice tower is at least 4; secondly, it is necessary to arrange the same number of strain measuring points in the same position on the two adjacent main members;and thirdly, the transient analysis technology is a mature and well-known technical means in the field, and self-programming or related commercial software can be used for the establishment and transient analysis of the numerical model of the lattice tower.

The above embodiments are only used to illustrate, but not to limit, the technical solutions of the present invention. Although the present invention has been described in detail with reference to the above embodiments, it should be understood by those ordinary skilled in the art that: the technical solutions recorded in the above embodiments can also be amended, or part of the technical features can be equivalently replaced. These amendments or replacements do not make the essence of the corresponding technical solutions deviate from the spirit and scope of the technical solutions of the embodiments of the present invention.

1. A horizontal two-dimensional displacement reconstruction method for a lattice tower structure based on multi-source heterogeneous data fusion, wherein a lattice tower is simplified into a thin-walled three-dimensional variable section cantilever beam; neutral layers are assumed to be located between two main members; a two-dimensional strain-displacement mapping method is used to calculate displacement with low sampling rate directly from strain; and horizontal two-dimensional dynamic displacement with high sampling rate is solved by taking the displacement with low sampling rate and acceleration as input values of a Kalman filter algorithm; the method comprises the following steps:
(1) evenly arranging 2M strain sensors along height on two adjacent main members of the lattice tower, with the minimum number of the strain sensors of 8; and arranging one horizontal two-dimensional acceleration sensor at a displacement point to be measured;
(2) decomposing strain response collected by the strain sensors according to directions of in-plane and out-of-plane vibration; processing the decomposed strain data {ε_{y}}_{M×1} and {ε_{z}}_{M×1} by using a stochastic subspace identification (SSI) method; drawing a stability diagram according to processing results; then judging a vibration mode order n participating in vibration according to the obtained stability diagram, wherein n is a natural number and does not exceed M; and extracting first n-order strain mode shape matrixes {Ψ_{y}}_{M×n}^{T} and {Ψ_{z}}_{M×n}^{T};
(3) calculating functional relationships y(x) and z(x) between horizontal distances y and z from any point of the main member to two neutral layers, and a height x of the point from the ground according to the lattice tower structure;
(4) performing polynomial fitting on the first n-order strain mode shapes and the height x of the strain sensor arrangement points from the ground, to obtain strain mode shape functions Ψᵢ^{y}(x) and Ψᵢ^{z}(x); then regarding
$$\frac{{Ψ}_{i}^{y} ( x )}{y ( x )} and \frac{{Ψ}_{i}^{z} ( x )}{z ( x )}$$
as functions as a whole, and expanding respectively according to Taylor formula; doubly integrating expansion results and substituting boundary conditions of bottom fixing of the lattice tower structure to obtain displacement mode shape functions Φᵢ^{y}(x) and Φᵢ^{z}(x);
(5) solving modal coordinates {q_{y}}_{n×1} and {q_{z}}_{n×1} of the lattice tower during vibration in two directions by a least squares method under the condition that the strain mode shape matrixes {Ψ_{y}}_{M×n}^{T} and {Ψ_{z}}_{M×n}^{T} of the lattice tower and the strain data {ε_{y}}_{M×1} and {ε_{z}}_{M×1} after orthogonal decomposition are known;
(6) substituting the height coordinate x of the displacement point to be measured on the lattice tower into the displacement mode shape functions Φᵢ^{y}(x) and Φᵢ^{z}(x) to obtain corresponding displacement mode shape function values, and multiplying the obtained displacement mode shape function values and the modal coordinates to obtain low sampling rate dynamic displacements u_{y} and u_{z} of the point;
(7) taking the y-direction acceleration a_{y} of the displacement point to be measured collected by the acceleration sensor and the calculated y-direction displacement u_{y} as a set of state variables, and taking the z-direction acceleration a_{z} and the calculated z-direction displacement u_{z} as another set of state variables; and respectively inputting the state variables into a multi-rate Kalman filter algorithm to reconstruct final horizontal two-dimensional dynamic displacement with high sampling rate.
